(19) United States
(12) Patent Application Publication
(10) Pub. No.: US 2013/0051139 A1
(43) Pub. Date: Feb. 28, 2013

(54) Resetting Phase Change Memory Bits

(71) Applicants: Rick K. Dodge, Santa Clara, CA (US); Timothy Langtry, San Jose, CA (US)

(72) Inventors: Rick K. Dodge, Santa Clara, CA (US); Timothy Langtry, San Jose, CA (US)

(21) Appl. No.: 13/646,861

(22) Filed: Oct. 8, 2012

Related U.S. Application Data
(63) Continuation of application No. 12/624,821, filed on Nov. 24, 2009, now abandoned.

(51) Int. Cl. G11C 11/00

(52) U.S. Cl. 365/163

(57) ABSTRACT

After determining that a reset pulse has reached its programmed threshold voltage level, a lower voltage verify can be conducted. This can be followed by another program step to increase the programmed threshold voltage. By avoiding the need for subsequent verification after the cell has reached its desired threshold level, read disturbs may be reduced in some embodiments. In some embodiments, by using lower voltages, it is not necessary to apply higher bias voltages to de-selected cells which may result in current leakage.

### CROSS-REFERENCE TO RELATED APPLICATIONS

This application is a continuation of U.S. patent application Ser. No. 12/624,821, filed on Nov. 24, 2009.

### BACKGROUND

This invention relates generally to semiconductor memories.

Phase change memory devices use phase change materials, i.e., materials that may be electrically switched between a generally amorphous and a generally crystalline state, as an electronic memory. One type of memory element utilizes a phase change material that may be, in one application, electrically switched between generally amorphous and generally crystalline local orders or between different detectable states of local order across the entire spectrum between completely amorphous and completely crystalline states.

### BRIEF DESCRIPTION OF THE DRAWINGS

FIG. 1 is a circuit diagram for one embodiment of the present invention;

FIG. 2 is a circuit diagram for the current sources for the read/write circuits shown in FIG. 1;

FIG. 3 is a plot of current versus time for a reset command and the resulting initial enable current mirror signal in accordance with one embodiment of the present invention;

FIG. 4 is a flow chart for one embodiment of the present invention;

FIG. 5 is a flow chart for one embodiment of the present invention;

FIG. 6 is a system depiction according to one embodiment of the present invention;

FIG. 7 is a hypothetical graph of percentage of possible bits versus threshold voltage according to one embodiment; and

FIG. 8 is a flow chart for one embodiment.

### DETAILED DESCRIPTION

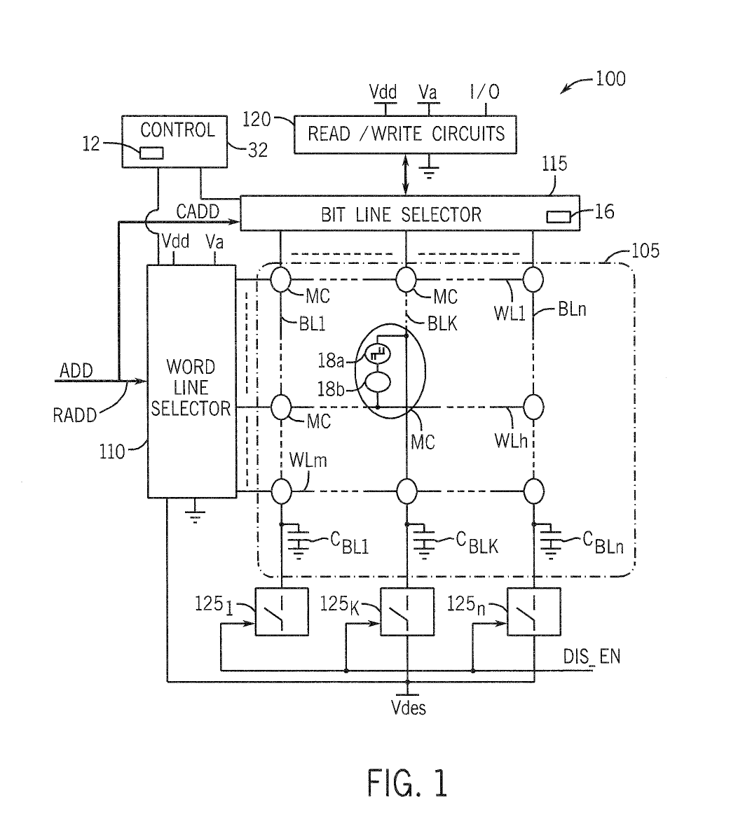

Referring to FIG. 1, in one embodiment, a memory 100 may include an array of memory cells MC arranged in rows WL and columns BL in accordance with one embodiment of the present invention. While a relatively small array is illustrated, the present invention is in no way limited to any particular size of an array. While the terms “rows,” “word lines,” “bit lines,” and “columns” are used herein, they are merely meant to be illustrative and are not limiting with respect to the type and style of the sensed array.

The memory device 100 includes a plurality of memory cells MC typically arranged in an array 105. The memory cells MC in the matrix 105 may be arranged in m rows and n columns with a word line WL1-WLm associated with each matrix row, and a bit line BL1-BLn associated with each matrix column.

The memory device 100, in one embodiment, may also include a number of auxiliary lines including a supply voltage line Vdd, distributing a supply voltage Vdd through a chip including the memory device 100, and a ground voltage line GND distributing a ground voltage. A high voltage supply line Va may provide a relatively high voltage, generated by devices (e.g. charge-pump voltage boosters not shown in the drawing) integrated on the same chip, or externally supplied to the memory device 100.

The cell MC may be any memory cell including a phase change memory cell. Examples of phase change memory cells include those using chalcogenide memory element 18a and an access, select, or threshold device 18b coupled in series to the device 18a. The threshold device 18b may be an ovonic threshold switch that can be made of a chalcogenide alloy that does not exhibit an amorphous to crystalline phase change and which undergoes a rapid, electric field initiated change in electrical conductivity that persists only so long as a holding voltage is present.

A memory cell MC in the array 105 is connected to a respective one of the word lines WL1-WLm and a respective one of the bit lines BL1-BLn. In particular, the storage element 18a may have a first terminal connected to the respective bit line BL1-BLn and a second terminal connected to a first terminal of the associated device 18b. The device 18b may have a second terminal connected to a word line WL1-WLm. Alternatively, the storage element 18a may be connected to the respective word line WL1-WLm and the device 18b, associated with the storage element 18a, may be connected to the respective bit line BL1-BLn.

A memory cell MC within the array 105 is accessed by selecting the corresponding row and column pair, i.e. by selecting the corresponding word line and bit line pair. Word line selector circuits 110 and bit line selector circuits 115 may perform the selection of the word lines and of the bit lines on the basis of a row address binary code RADD and a column address binary code CADD, respectively, part of a memory address binary code ADD, for example received by the memory device 100 from a device external to the memory (e.g., a microprocessor). The word line selector circuits 110 may decode the row address code RADD and select a corresponding one of the word lines WL1-WLm, identified by the specific row address code RADD received. The bit line selector circuits 115 may decode the column address code CADD and select a corresponding bit line or, more generally, a corresponding bit line packet of the bit lines BL1-BLn. For example, the number of selected bit lines depending on the number of data words that can be read during a burst reading operation on the memory device 100. A bit line BL1-BLn may be identified by the received specific column address code CADD.

The bit line selector circuits 115 interface with read/write circuits 120. The read/write circuits 120 enable the writing of desired logic values into the selected memory cells MC, and reading of the logic values currently stored therein. For example, the read/write circuits 120 include sense amplifiers together with comparators, reference current/voltage generators, and current pulse generators for reading the logic values stored in the memory cells MC.

During a reading or a writing operation, the word line selection circuits 110 may lower the voltage of a selected one of the word lines WL1-WLm to a word line selection voltage V_{WL} (for example, having a value equal to 0V—the ground potential), while the remaining word lines may be kept at the word line de-selection voltage Vdes in one embodiment. Similarly, the bit line selection circuits 115 may couple a selected one of the bit lines BL1-BLn (more typically, a selected bit line packet) to the read/write circuits 120, while the remaining, non-selected bit lines may be left floating or held at the de-selection voltage, Vdes. Typically, when the memory device 100 is accessed, the read/write circuits 120 force a suitable current pulse into each selected bit line BL1-BLn. The pulse amplitude depends on the reading or writing operations to be performed.

In particular, during a reading operation a relatively high read current pulse is applied to each selected bit line in one embodiment. When the read current is forced into each selected bit line BL1-BLn, the respective bit line voltage raises towards a corresponding steady-state value, depending on the resistance of the storage element 18a, i.e., on the logic value stored in the selected memory cell MC. The duration of the transient depends on the state of the storage element 18a. If the storage element 18a is in the crystalline or set state and the threshold device 18b is switched on, a cell current flowing through the selected memory cell MC has an amplitude greater than the amplitude in the case where the storage element 18a is in the higher resistivity or reset state.

The logic value stored in the memory cell MC may, in one embodiment, be evaluated by means of a comparison of the bit line voltage (or another voltage related to the bit line voltage) at, or close to, the steady state thereof with a suitable reference voltage, for example, obtained exploiting a service reference memory cell. The reference voltage can, for example, be chosen to be an intermediate value between the bit line voltage when a logic value “0” is stored and the bit line voltage when a logic value “1” is stored.

The bit line discharge circuits 125₁-125ₙ may be implemented by means of transistors, particularly N-channel MOSFETs having a drain terminal connected to the corresponding bit line BL1-BLn, a source terminal connected to a de-selection voltage supply line Vdes providing the de-selection voltage Vdes and a gate terminal controlled by a discharge enable signal DIS_EN in one embodiment. Before starting a writing or a reading operation, the discharge enable signal DIS_EN may be temporarily asserted to a sufficiently high positive voltage, so that all the discharge MOSFETs turn on and connect the bit lines BL1-BLn to the de-selection voltage supply line Vdes.

A phase change material, used in the devices 18a and 18b, may include a chalcogenide material. A chalcogenide material may be a material that includes at least one element from column VI of the periodic table or may be a material that includes one or more of the chalcogen elements, e.g., any of the elements of tellurium, sulfur, or selenium. Chalcogenide materials may be non-volatile memory materials that may be used to store information that is retained even after the electrical power is removed.

In one embodiment, the phase change material may be chalcogenide element composition from the class of tellurium-germanium-antimony (TeₓGe_{y}Sb_{z}) material or a GeSbTe alloy, although the scope of the present invention is not limited to just these materials.

The bit line selector circuits 115 may include a current source 16. The current source 16 may controllably provide the current needed by the selected bit line for either reading, writing, or writing either a set or a reset bit. Each of these operations requires a different current. In accordance with one embodiment of the present invention, a single current source 16 controllably supplies the appropriate current for each of these operations. Control over the current supplied may be provided by a control 32. In one embodiment, the control 32 may be a processor and may include a state machine 12.

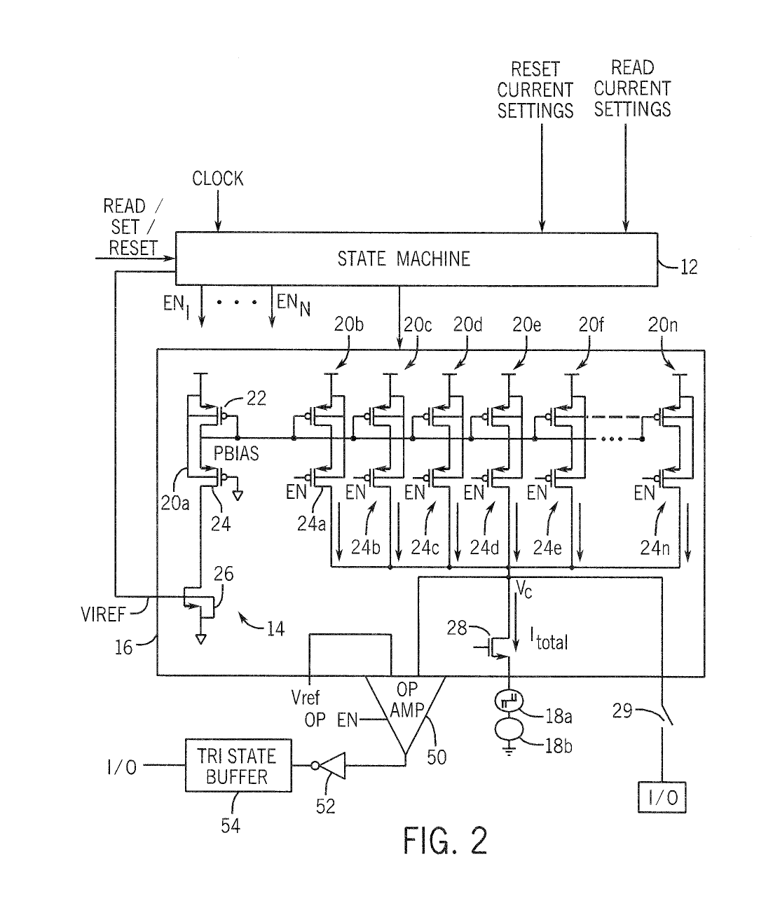

Referring to FIG. 2, the state machine 12 of the control 32 may communicate with the current source 16. In particular, the state machine 12 may receive reset current settings and read current settings as indicated in FIG. 2. The reset current settings provide information about what current should be provided for writing a reset bit. Similarly, the read current settings provide information about what current should be used for reading. The information may change from wafer run to run. That is, variations in wafers in particular runs may be accounted for by providing appropriate inputs to the state machine 12. In addition, the state machine 12 receives information about whether a read operation is implemented or whether a set or reset bit is to be written. Also, the state machine receives a clock signal.

The state machine 12 outputs a number of enable signals EN₁-EN_{N}. In one embodiment of the present invention, N is equal to 32. However, different numbers of enable signals EN may be utilized to provide different granularities in the amount of current provided by the current source 16.

The state machine 12 may also either generate or pass through an external voltage signal VIREF that is applied to the gate of a transistor 26. That signal may be generated, in some embodiments, based on the read current settings provided from external sources, for example, based on the characteristics of a particular wafer run. The amount of drive on the gate of the transistor 26 may control the potential at the node PBIAS. Thus, in one embodiment of the present invention, the amount of current developed by the cascode 20a may be controlled.

In one embodiment of the present invention, the cascode 20a and the transistor 26 are part of a reference circuit which generates a reference current. That reference current from the reference circuit may then be mirrored into any of the cascodes 20b-20n. In one embodiment, the number of cascodes 20b-20n may be equal to the number of enable signals EN from the state machine 12. As a result, the state machine 12 can enable all or any subset of the cascodes 20b-20n. This is because, in one embodiment, each cascode may have a transistor 24 (i.e., one of the transistors 24a-24n), which receives an enable signal EN as indicated. In other words, each enable signal from the state machine is designated for a particular cascode 20b-20n in one embodiment of the present invention.

Thus, the amount of current indicated by the arrows coming from each cascode 24a-24n may be determined in two ways. In the first way, the state machine 12 determines whether or not the cascode 24 is enabled. If a cascode is enabled, the amount of current that it passes is determined by the reference circuit and, particularly, by the drive on the gate of the transistor 26.

The current through the transistor 26 and its cascode 20a is mirrored into each of the cascodes 20b-20n. In one embodiment of the present invention, that current is approximately 5 microamps.

The node VC at the base of the cascodes 20b-20n receives whatever current is mirrored into each active cascode 20. The node VC then develops a voltage which is determined by the resistance across the selected cell MC, made up of the memory element 18a and the threshold device 18b. Thus, if the cell is in a reset state, one voltage is developed at the node VC and if the cell is in the set state, a different voltage is generated at the node VC. A pass transistor 28 provides the current through the node VC and through the threshold device 18b to ground. The node VC may also be coupled through a switch 29 to an I/O pad so that the voltage VC may be monitored externally, for example, to determine what the reference voltage should be.

The node VC may also be coupled to an operational amplifier 50, in one embodiment, that compares the voltage at the node VC to a reference voltage VREF from an external source, for example. In one embodiment, the reference voltage may be set between the voltage levels at the node VC for the set and reset bits. The operational amplifier 50 is only turned on in the read mode by using the enable signal OP EN.

The output from the operational amplifier 50 is passed through an inverter 52 to a tristate buffer 54. Thus, the operational amplifier acts as a sense amplifier to develop an output signal, indicated as I/O in FIG. 2, indicating the state of a sensed cell.

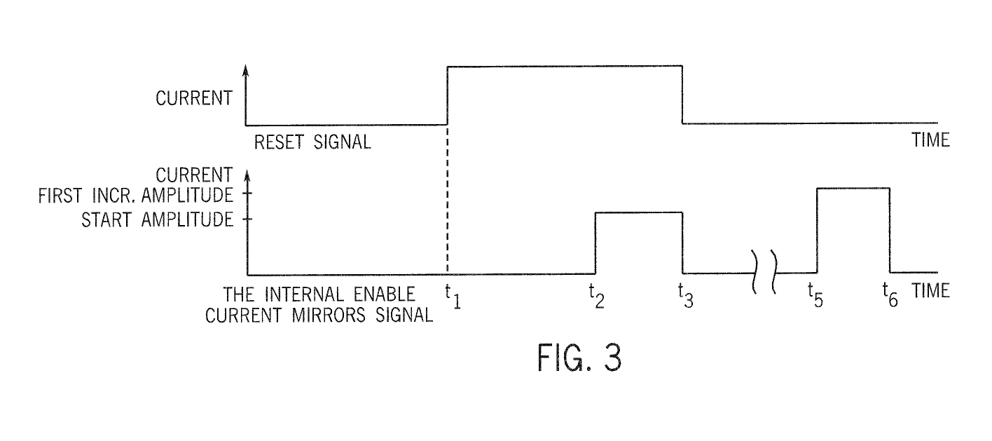

Referring to FIG. 3, a command to write a reset level to a selected cell may have the characteristics over time as indicated in the upper plot. The internal signal, indicated in the lower plot, results from the write reset level command. This internal signal may have an adjustable delay between the time t1 and t2 in some embodiments. This adjustable delay may allow the pulse width of the resulting signal, indicated between the times t2 and t3 in FIG. 3, to be controllably adjusted. As a result of a reset command signal of a larger pulse width, a smaller pulse width internal command signal may be generated. That internal command signal may be a square wave in one embodiment. Thus, the current to write a reset bit into the selected cell may be a square wave of determined pulse width. The determination of the pulse width may be dynamically controlled by the state machine 12 in one embodiment of the present invention by setting the time delay between the time that the state machine 12 receives the external write command, indicated as a set signal, and the time, t2, when the state machine 12 provides the enable signal to the appropriate cascodes 20b-20n to generate current to the node V_{C}.

After an initial pulse is applied between time t2 and time t3, one or more additional pulses may be applied in some embodiments of the present invention. The initial pulse may be at a relatively lower start amplitude as indicated in FIG. 3. Some bits may need a higher amplitude programming pulse than other bits to reach the reset state. A check determines whether or not any bits still need to be reset after the initial start pulse amplitude is applied. If so, a second pulse may be applied, for example, between times t5 and t6, as indicated in FIG. 3. The start pulse amplitude may be incremented to provide a slightly higher first incremented amplitude, second pulse as indicated in FIG. 3.

Thereafter, progressively higher pulses may be applied until all the bits are reset or until a maximum amplitude is reached. The maximum amplitude may be an amplitude that would lead to early wear out or difficulty in achieving a subsequent set state. The higher amplitude pulses may be achieved by simply activating additional current mirrors as needed in some embodiments.

In one embodiment, the square pulse, shown in FIG. 3, may be generated by operating a predetermined number of the cascodes 20. For example, in one embodiment, 28 out of 32 available cascodes may be operated between the times t2 and t3.

The width of the programming pulse, and the slope of its ramp may be set based on inputs to the state machine 12. Those inputs may include a variety of data including the characteristics of the memory element 18a and the particular characteristics of a run of wafers.

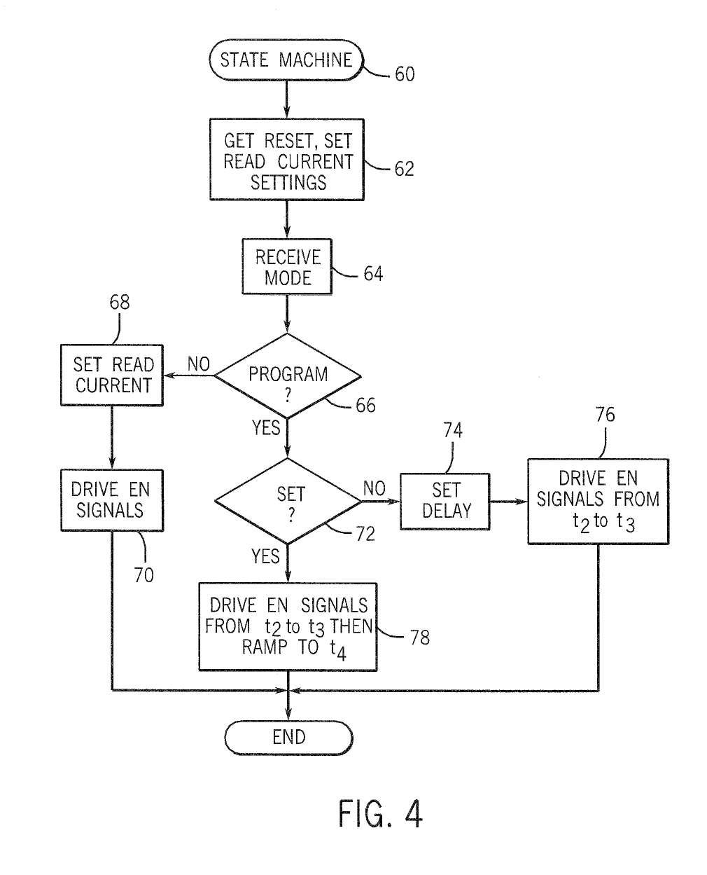

Referring to FIG. 4, the state machine code 60 may initially get the reset, set, and read current settings as indicated in block 62. The code 60 may be software, firmware, or hardware. These settings may be provided from external sources or may be calculated based on available information. The operation to be performed is then received and the appropriate currents calculated as indicated in block 64. At diamond 66, a check determines whether the state machine 12 is in the program mode. If so, a first check is whether or not a set bit will be written as indicated in diamond 72. If so, the delay between the times t1 and t2 is determined (block 74) and the appropriate number of enable signals are generated between the times t2 (block 76) and t3 (block 76).

Conversely, if a reset bit is to be programmed, the appropriate number of enable signals are provided between the time t2 through t3 (block 78). Thereafter, the current is ramped down to time t4. The ramping may be implemented, in one embodiment, by progressively turning off enable signals EN using the clock input to the state machine 12 to time the progressive turning off of the cascode enable signals.

If the memory device 100 is in the read mode, then the read current may be set as indicated in block 68. This may be done by controlling the signal VIREF to set the reference column current in one embodiment. In some embodiments, the read current may be set wafer to wafer at a level between the set and reset bits. However, other arrangements are also possible. In the read mode, the operational amplifier enable signal OP EN is enabled to turn on the operational amplifiers 50. The enable signals are then driven, as indicated in block 70, to provide the desired read current.

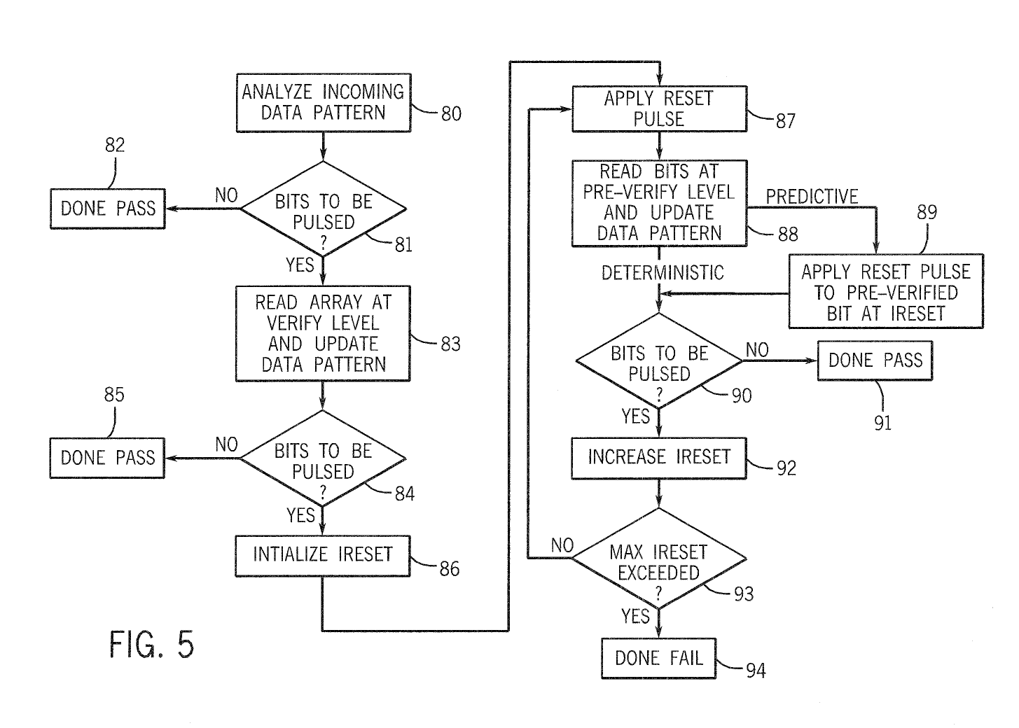

Referring to FIG. 5, in the case where a reset bit is to be programmed, in one embodiment, after the block 76 in FIG. 4, a series of pulses may be applied to program the reset bit. This may be necessary because some bits may need a higher current to be programmed than other bits. However at the same time, it is desirable not to exceed a maximum safe pulse amplitude.

To this end, initially, the data to program is received. Then, the data is read to determine which bits need to be reset as indicated in block 80. A check at diamond 81 determines whether any bits need a program pulse. If not (block 82), the flow ends.

If so, the data is then read at a lower verify voltage level selected for the technology to determine which bits still need to be reset as indicated in block 83. This lower voltage verify level is lower than a conventional verify level. A lower level can be used because this “lower voltage verification” occurs at a point when the cell is programmed, but is not programmed to its final programmed threshold voltage level. As a result, a lower verify voltage can be used.

In diamond 84, a check again determines whether any of the bits still need the reset program pulse. If not (block 85), the flow ends. If so, the reset current is initialized (block 86) and a reset pulse is applied (block 87).

Then in block 88, the bits that received the program pulse are read at the pre-verify level and the data pattern is updated. In other words, it is determined whether the bits have reached their desired final threshold voltage. With respect to those bits that passed pre-verify, an additional reset pulse is applied to them. In some cases, this second reset pulse may be at the same level as the reset pulse applied in block 87. In other embodiments, a slightly higher reset pulse may be used. The exact nature of the reset pulse may vary in different situations. At this point, it is known what the last pulse was and it is known that the last pulse got at least one bit to the lower voltage verify level or higher. With knowledge of the cell current versus voltage characteristics and, particularly, the characteristics of threshold voltage versus current or resistance versus current, it is known that the cell will follow a certain behavior. Thus, having been given one point, as the result of the read operation in block 88, the behavior after another pulse can be predicted based on the known information. In other words, it can be determined what level of second pulse is needed to assure that the cell or bit will be placed at a known, desired location on its threshold voltage versus current curve.

In many cases, simply applying the same voltage again is sufficient. In some cases, an increment may be added. Thus, as indicated in block 89, a second reset pulse is applied to the pre-verified bits at the reset current that was used in block 87 plus a delta X, which may be zero or a relatively small current in the range of 0 to 300 microAmps, in some embodiments. In one embodiment, the second reset pulse is about 100 microAmps higher than the prior pulse.

The more the delta is increased, the higher the predictable increase in threshold voltage or resistance. To get a bigger difference between the results after block 89, in order to maintain more margin of the final threshold voltage, the delta may increase.

Thus, in some embodiments, the lower voltage verify may be separated from the final threshold voltage. The final threshold voltage may be arrived at without another verify after a lower voltage verify step. Thus, the bit does not see a verify condition after the last reset pulse. This verify, after the last reset pulse, can give rise to a disturb issue. This means that the verify may be achieved at a lower voltage, avoiding a read disturb in some embodiments.

In addition, with conventional technologies, a relatively high inhibit bias must be used during the final verify step after the final reset pulse has been applied. This high inhibit bias is applied on the de-selected cells. The high voltage on the de-selected cells results in more leakage than what occurs with some embodiments of the present invention.

Then a check at diamond 90 determines whether anymore bits need to be pulsed. If not, the flow is over, as indicated in block 91. Otherwise, the reset current may be increased incrementally in block 92. A check at diamond 93 determines whether the maximum reset current for the technology has been exceeded. If so, the programming has failed, as indicated in block 94. Otherwise, the flow returns to block 87 to apply a slightly higher reset pulse and the flow iterates.

Since each bit in the array may have different optimal pulse amplitude for reset, different pulse amplitudes may be used. However, applying at pulse greater than the optimal pulse may damage the bit leading to early wear out, and difficulty in achieving a subsequent set state.

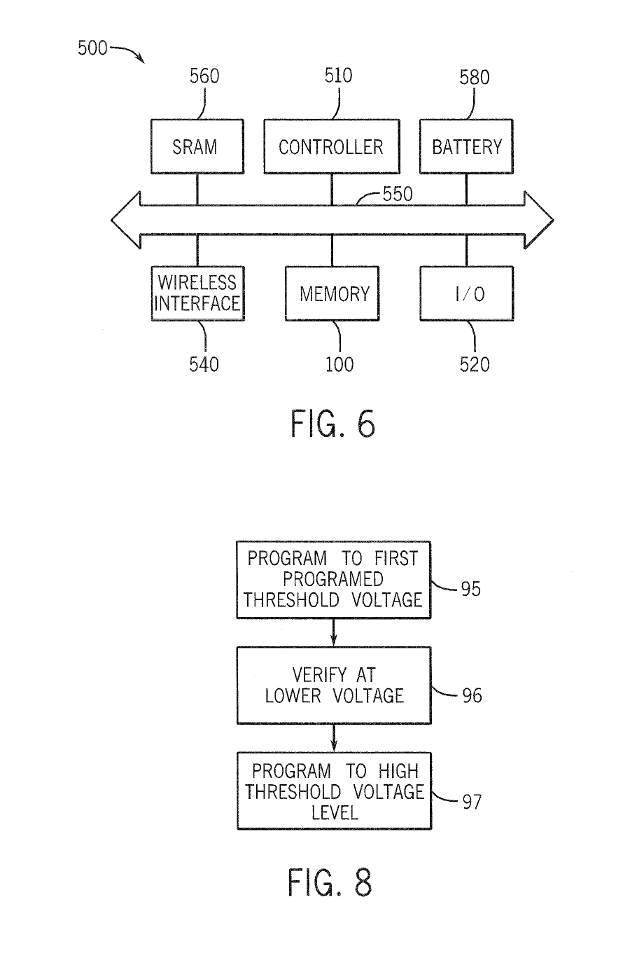

Turning to FIG. 6, a portion of a system 500 in accordance with an embodiment of the present invention is described. System 500 may be used in wireless devices such as, for example, a personal digital assistant (PDA), a laptop or portable computer with wireless capability, a web tablet, a wireless telephone, a pager, an instant messaging device, a digital music player, a digital camera, or other devices that may be adapted to transmit and/or receive information wirelessly. System 500 may be used in any of the following systems: a wireless local area network (WLAN) system, a wireless personal area network (WPAN) system, or a cellular network, although the scope of the present invention is not limited in this respect.

System 500 may include a controller 510, an input/output (I/O) device 520 (e.g. a keypad, display), a memory 100, a wireless interface 540, and a static random access memory (SRAM) 560 and coupled to each other via a bus 550. A battery 580 may supply power to the system 500 in one embodiment. It should be noted that the scope of the present invention is not limited to embodiments having any or all of these components.

Controller 510 may comprise, for example, one or more microprocessors, digital signal processors, micro-controllers, or the like. Memory 100 may be used to store messages transmitted to or by system 500. Memory 100 may also optionally be used to store instructions that are executed by controller 510 during the operation of system 500, and may be used to store user data. The instructions may be stored as digital information and the user data, as disclosed herein, may be stored in one section of the memory as digital data and in another section as analog memory. As another example, a given section at one time may be labeled as such and store digital information, and then later may be relabeled and reconfigured to store analog information. Memory 100 may be provided by one or more different types of memory. For example, memory 100 may comprise a volatile memory (any type of random access memory), a non-volatile memory such as a flash memory, and/or memory 100 illustrated in FIG. 1.

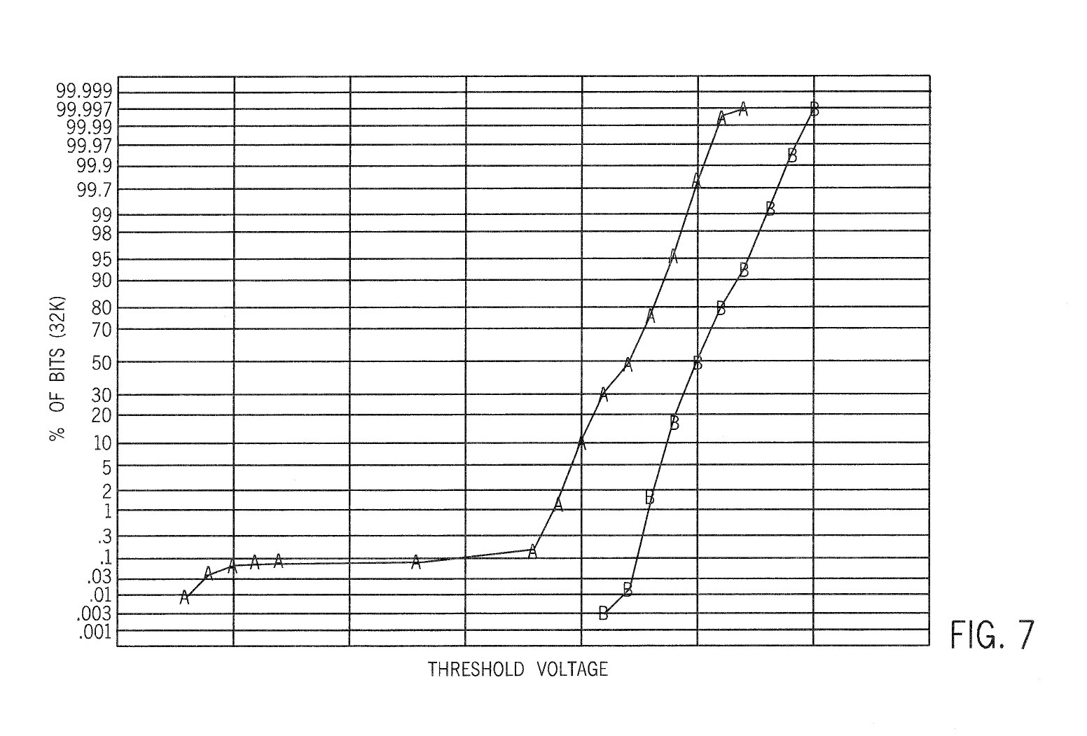

Referring to FIG. 7, this is a hypothetical graph of percentage of bits that pass the verify in block 88 versus threshold voltage. The first curve to the left is the results with only the deterministic test (block 88) and without the use of the predictive technique of block 89. The results with block 89, using the predicted reset pulse characteristics, shows that applying the augmented pulse (100 microAmps higher) increases the threshold voltage. In some embodiments, the threshold voltage may be increased by about 0.5 volts.

Moreover, in some embodiments, there is no need to verify after this final reset pulse is applied, eliminating the possibility of any kind of read disturb during verify. As a result, the lower voltage verify can be done when the cell is at a lower programmed threshold voltage. Then, a lower verify voltage may be used. Thereafter, the cell can be programmed to a higher programmed threshold voltage, without repeating the verify step. The repeated verify, necessarily at a higher voltage level, would be more likely to cause a read disturb.

Referring to FIG. 8, a sequence is illustrated for programming a phase change memory cell to a programmed state. In some embodiments, the sequence may be implemented in software and in other embodiments it may be implemented in hardware. In one embodiment, the sequence may be in a software implemented embodiment wherein the software is stored in a memory, such as a semiconductor, optical, or magnetic memory. In one embodiment, the software may be stored in the state machine 12, shown in FIG. 2.

Initially, the cell is exposed to progressively higher reset programming pulses until the cell is programmed to a first programmed threshold voltage in block 95. In block 96, the programming to the programmed threshold voltage is verified. Then, the cell is programmed to a higher threshold voltage in block 97. At this point, the programming is completed and an ensuing verify step is not needed, nor is it desirable.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
refraining from verifying a phase change memory cell after programming said phase change memory cell to its final programmed reset threshold voltage level.

2. The method of claim 1 including:
applying a reset pulse to a set cell in a phase change memory;
verifying that the cell has been programmed to above a first programmed threshold voltage;
programming said cell to a second programmed threshold level higher than said first programmed threshold voltage; and
refraining from verifying said cell at said second programmed threshold voltage.

3. The method of claim 2 including using known characteristics of the cell to determine the nature of a current pulse to apply to the cell after the cell has reached its first programmed threshold voltage.

4. The method of claim 2 including applying a slightly higher current applied after the cell has reached its first programmed threshold voltage.

5. The method of claim 4 including applying less than 300 microAmps of additional current.

6. The method of claim 5 including applying about 100 microAmps of additional current.

7. The method of claim 2 including avoiding verification of the cell after applying the last reset pulse.

8. The method of claim 2 including successively applying pulses of higher magnitude until the cell reaches the second programmed threshold level.

9. The method of claim 2 including using the cell's threshold voltage versus current curve to determine the nature of the pulse applied after the cell has reached its threshold level.

10. An apparatus comprising:
an array of phase change memory cells; and
a control to program a cell to a first programmed threshold voltage, to verify the cell at said first programmed threshold voltage and then to program said cell to a second programmed reset threshold voltage, higher than said first programmed threshold voltage, without verification after reaching said second programmed reset threshold voltage.

11. The apparatus of claim 10, said control to apply a slightly higher current after the cell has reached its first programmed threshold voltage.

12. The apparatus of claim 11, said control to apply less than 300 microAmps of additional current.

13. The apparatus of claim 12, said control to apply about 100 microAmps of additional current.

14. The apparatus of claim 10 wherein the cell is not verified after being programmed to a desired reset threshold voltage.

15. The apparatus of claim 10 wherein said control to successively apply pulses of higher magnitude until said cell reaches its desired reset threshold level.

16. A non-transitory computer readable medium storing instructions executed by a computer to:
program a phase change memory cell to a first programmed threshold voltage;
verify that the cell has reached a programmed threshold voltage level; and
program said cell to a higher reset threshold voltage level without an ensuing verify.

17. The medium of claim 16 further storing instructions to progressively apply higher programming voltages to a cell to be programmed.

18. The medium of claim 16 further storing instructions to provide a current pulse of less than 300 microAmps to said cell after reaching said first program voltage threshold level.
